(19) United States
(12) Patent Application Publication
(10) Pub. No.: US 2010/0315773 A1
(43) Pub. Date: Dec. 16, 2010

(54) FOOT HEIGHT ADJUSTMENT SYSTEM AND METHOD

(75) Inventor: Mark D. Senatori, The Woodlands, TX (US)

Correspondence Address: HEWLETT-PACKARD COMPANY;Intellectual Property Administration, 3404 E. Harmony Road, Mail Stop 35, FORT COLLINS, CO, 80528, US

(73) Assignee: HEWLETT-PACKARD DEVELOPMENT COMPANY, L.P., Houston, TX (US)

(21) Appl. No.: 12/483,538

(22) Filed: Jun. 12, 2009

(51) Int. Cl. H05K 7/00; E05D 7/00

(52) U.S. Cl. 361/679.55; 16/221; 16/277; 361/679.56

(57) ABSTRACT

A foot height adjustment system is provided. The system can include a clamshell device comprising a first member having an exterior surface and a pivotably connected second member. The pivotable connection between the members can comprise at least one hinge. At least one foot can be disposed within an aperture disposed within the first member. The one foot can project a first distance from the exterior surface of the first member. An actuator, adapted to reversibly increase the projection of the at least one foot from the exterior surface of the first member to a second distance when the second member is pivoted about the at least one hinge, can link the second member and the at least one foot. The second distance can be greater than the first distance.

### BACKGROUND OF THE INVENTION

### Description of the Related Art

This section is intended to introduce the reader to various aspects of art which may be related to one or more aspects of the present invention as described and claimed below. This discussion is believed helpful in providing the reader with background information, thereby facilitating a better understanding of various aspects of the present invention. Accordingly, it should be understood by the reader that the provided information should be read in this light and not as an admission of any prior art.

Clamshell electronic devices are characterized by having two pivotably attached members joined by a hinged connection. Either, or both, of the members can house one or more heat-producing electronic components, for example one or more integrated circuits, storage devices, memory modules, display devices, and the like. Heat generated within the clamshell electronic device must be vented or otherwise exhausted from the device in order to maintain proper and efficient operation of the electronics contained within the device. The heat is often permitted to escape the device via one or more slots, holes, or similar ventilation features disposed about the device.

Frequently, the clamshell electronic devices are designed for portability, and to facilitate the portable aspect of the device, protrusions from the clamshell device are minimized. The lack of protrusions from the device often means that airflow through the one or more slots, holes, or similar ventilation features disposed about the device is hindered or blocked completely when the device is placed on a surface such as a table or desk. Such hindered or impeded airflow can adversely affect the performance or life expectancy of the electronic device.

### SUMMARY OF THE INVENTION

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

A foot height adjustment system is provided. The system can include a clamshell device comprising a first member having an exterior surface and a pivotably connected second member. The pivotable connection between the members can comprise at least one hinge. At least one foot can be disposed within an aperture disposed within the first member. The one foot can project a first distance from the exterior surface of the first member. An actuator, adapted to reversibly increase the projection of the at least one foot from the exterior surface of the first member to a second distance when the second member is pivoted about the at least one hinge, can link the second member and the at least one foot. The second distance can be greater than the first distance.

A height adjustable clamshell electronic device is also provided. A clamshell electronic device can comprise a first member and a second member pivotably connected along a single axis using at least one hinge. A plurality of adjustable feet can be individually disposed in a respective plurality of apertures disposed about the first member. The plurality of feet can project a first distance from the exterior surface of the first member when the first member and the second member forming the clamshell electronic device are disposed at a first angle. The plurality of feet can project a second distance from the exterior surface of the first member when the first member and the second member forming the clamshell electronic device are disposed at a second angle. The second member can be operably connected to all or a portion of the plurality of adjustable feet.

A method for adjusting the foot height a clamshell device is also provided. A first member and a second member can be pivotably connected using at least one hinge having a single axis of rotation. At least one foot can be at least partially disposed in at least one aperture disposed at least partially within the first member. The second member can be operably connected to the at least one foot using an actuator. The projection of the at least one foot from an exterior surface of the first member can be adjusted from a first distance to a second distance by rotating the second member about the hinge from a first position to a second position.

As used herein, the term “clamshell electronic device” refers to an electronics form factor comprising two or more pivotably connected sections or members. The pivotably connected members are connected and can fold via a hinge. The clamshell form factor is frequently used to refer to electronic devices, particularly portable electronic devices, for example mobile phones, portable computers, laptop computers, subnotebooks, the Game Boy® Advance SP and the Nintendo® DS. When the clamshell is disposed in an open position to create a larger form factor, one or more of the input/output (“I/O”) components are exposed, permitting user interaction with the device. When the clamshell is disposed in a “closed” position to create a smaller form factor, one or more of the I/O components will be hidden, limiting user interaction with the device.

As used herein, an “operative coupling” or components that are “operatively coupled” refers to two or more components that are mechanically linked such that an input to one component results in an input to the second component. The input to the second component can be proportionately greater, lesser, or the same as the input to the first component. The input to the second component can be in the same plane or a different plane than the input to the first component. The two or more components can be directly linked using one or more coupled or linked members or indirectly linked by one or more electrical, or electromechanical devices, for example a solenoid or electromagnetic device.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

Advantages of one or more disclosed embodiments may become apparent upon reading the following detailed description and upon reference to the drawings in which:

FIG. 1 is a schematic diagram depicting an exemplary foot height adjustment system in an illustrative first position, according to one or more embodiments described herein;

FIG. 2 is a schematic diagram depicting the exemplary foot height adjustment system depicted in FIG. 1 in an illustrative second position, according to one or more embodiments described herein;

FIG. 3 is a schematic diagram depicting an exemplary actuator, according to one or more embodiments described herein;

FIG. 4 is a schematic diagram depicting an exemplary foot height adjustment system using the exemplary actuator depicted in FIG. 2 in an illustrative first position, according to one or more embodiments described herein;

FIG. 5 is a schematic diagram depicting the exemplary foot height adjustment system depicted in FIG. 4 in an illustrative second position, according to one or more embodiments described herein; and

FIG. 6 is a schematic diagram depicting the exemplary foot height adjustment system depicted in FIG. 4 in an illustrative first position, according to one or more embodiments described herein.

### DETAILED DESCRIPTION

A detailed description will now be provided. Each of the appended claims defines a separate invention, which for infringement purposes is recognized as including equivalents to the various elements or limitations specified in the claims. Depending on the context, all references below to the “invention” may in some cases refer to certain specific embodiments only. In other cases it will be recognized that references to the “invention” will refer to subject matter recited in one or more, but not necessarily all, of the claims. Each of the inventions will now be described in greater detail below, including specific embodiments, versions and examples, but the inventions are not limited to these embodiments, versions or examples, which are included to enable a person having ordinary skill in the art to make and use the inventions, when the information in this patent is combined with available information and technology.

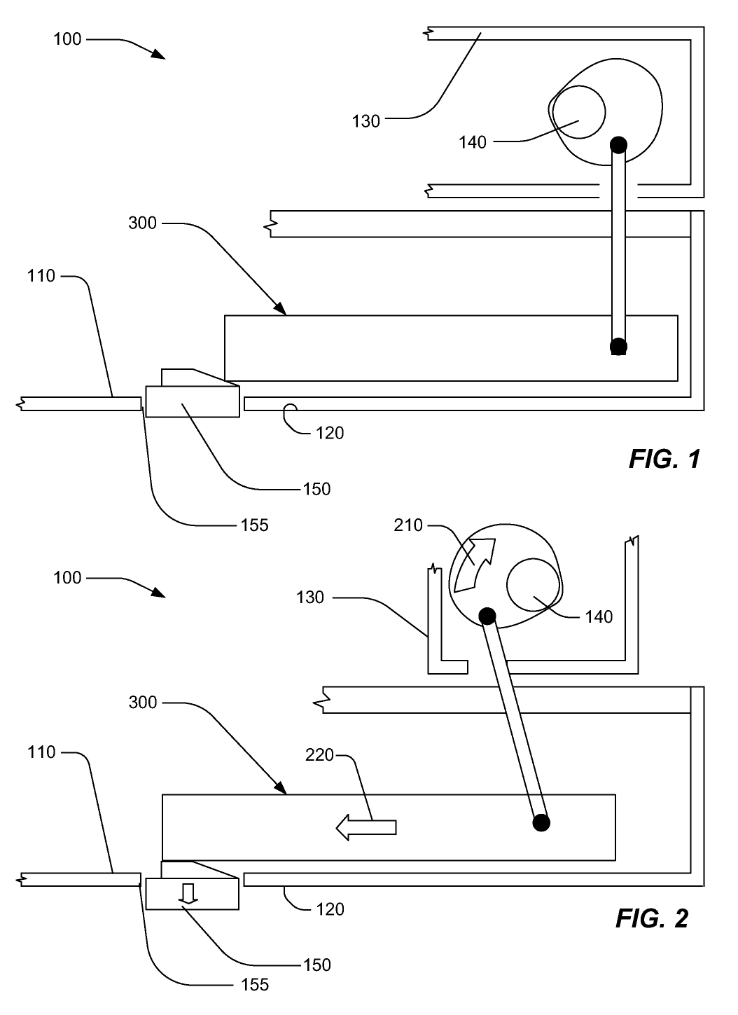

FIG. 1 is a schematic diagram depicting an exemplary foot height adjustment system 100 in an illustrative first position, according to one or more embodiments. In one or more embodiments, the system 100 can include a first member 110, having an external surface 120, and a second member 130 pivotably connected via one or more hinges 140. One or more feet 150 can be disposed in one or more apertures 155, the apertures disposed in, on, or about the first member 110. An actuator 300 can operably connect the second member 130 and the one or more feet 150.

In one or more embodiments, the first member 110, the second member 130 and the one or more hinges 140 can define a clamshell electronic device where the first member 110 and the second member 130 can be pivotably connected via the one or more hinges 140. The clamshell electronic device can include any system, device, or combination of systems and/or devices so disposed or arranged. Exemplary clamshell electronic devices can include, but are not limited to, cellular devices, portable digital assistants (“PDAs”), portable computing devices, laptop computing devices, ultraportable computing devices, handheld computing devices, gaming devices and the like. In one or more specific embodiments, the first member 110 can be similar in size and/or shape to the second member 130.

The first member 110 and the second member 130 can be generally planar members. In one or more specific embodiments, the first member 110 and the second member 130 can be disposed in a first, “closed” position as depicted in FIG. 1, where the plane defined by the first member 110 can be parallel to the plane defined by the second member 130. Since the first member 110 and the second member 130 can be pivotably connected, second member 130 can be pivoted about the one or more hinges 140 to assume any second “open” position, where the plane defined by the second member 130 can be any angle measured with respect to the plane defined by the first member 110.

In one or more specific embodiments, the first member 110 and the second member 130 can be a clamshell portable computing device, for example a laptop computer as exemplified by the Hewlett Packard HDX 18t series laptop computer, a mini-laptop computer as exemplified by the Hewlett Packard Mini 1000 XP series mini-laptop computer, or an ultraportable computer as exemplified by the Hewlett Packard Pavilion dv4t series ultraportable computer. In one or more specific embodiments, one or more input devices, for example one or more keyboards or pointing devices, can be disposed in, on, or about the first member 110. In one or more specific embodiments, an output device, for example a liquid crystal display (“LCD”), can be disposed in, on, or about the second member 130.

The one or more hinges 140 can be any system, device, or combination of systems and/or devices suitable for the operably connecting and/or communicatively connecting the first and second members 110, 130. In one or more embodiments, the one or more hinges can be a piano style hinge, a friction hinge, or the like. The one or more hinges 140 can, in one or more embodiments, define a single axis of rotation about which the first member 110 or the second member 130 can rotate.

In one or more embodiments, one or more feet 150 can be individually disposed in one or more respective apertures 155. The one or more apertures 155 can be disposed in, on, or about the first member 110 in any number, frequency, or arrangement. In one or more embodiments, although not shown in FIG. 1, one or more seals, gaskets, grommets, or the like can be disposed in all or a portion of the one or more apertures 155 to minimize or prevent the passage of particulate and/or liquid contaminants through any space existent between the one or more feet 150 and the one or more apertures 155.

The one or more feet 150 can be any member, device, system, or any combination thereof suitable for providing a stable base supporting the first member 110 and/or the clamshell electronic device. In one or more embodiments, the one or more feet 150 can be partially or completely formed using an elastomeric material to minimize or prevent slippage when the first member 110 and/or clamshell electronic device is placed on a smooth surface. In one or more embodiments, the one or more feet 150 can project a first distance from the exterior surface 120 of the first member 110 when the clamshell device is in the first position as depicted in FIG. 1. In one or more embodiments, the first distance can range from as little as about 1 mm; about 2 mm; about 3 mm; or about 5 mm; to as much as about 7 mm; about 10 mm; about 15 mm; or about 20 mm.

The actuator 300 can include one or more systems, devices, or any combination of systems and/or devices suitable for transferring or translating the rotation of the second member 130 to a linear output force, for example the force exerted on the one or more feet 150. The actuator 300 can physically or mechanically link the second member 130 and the one or more feet 150, translating or transferring all or a portion of the rotational motion of the second member 130 about the one or more hinges 140 to the one or more feet 150. In one or more embodiments, the one or more actuators 300 can include a translatable or otherwise moveable member that can be proportionately or disproportionately displaced as the second member 130 is rotated about the hinge 140.

FIG. 2 is a schematic diagram depicting the exemplary foot height adjustment system 100 depicted in FIG. 1 in an illustrative second position, according to one or more embodiments. In one or more embodiments, the second member 130 can be reversibly rotated 210 about the one or more hinges 140 to the exemplary second position depicted in FIG. 2. In one or more embodiments, the transverse plane defined by the first member 110 and transverse plane defined by the second member 130 can form any angle greater than about 0° when the clamshell device is disposed in the second position.

In one or more embodiments, the second member 130 can be rotated about the one or more hinges 140. The rotation of the second member 130 about the one or more hinges 140 can reversibly move, shift, reposition, or otherwise displace 220 the actuator 300 in a direction proximate the one or more feet 150. As the connecting member 300 impacts or otherwise contacts the one or more feet 150, the one or more feet 150 can be downwardly reversibly displaced 230, increasing the projection from the exterior surface 120 of the first member 110 to a second distance.

The terms “upward,” “downward,” “upwardly,” and “downwardly” and other like terms used herein refer to relative positions to another and are not intended, nor should be interpreted, to denote a particular absolute direction or spatial orientation. For example, a feature described as being on the “bottom” surface of a device could be on the “top” surface or a “side” surface of the device if the device is rotated or inverted; such rotation or inversion is envisioned to be within the scope of one or more claimed embodiments described herein.

In one or more embodiments, the second distance can be dependent upon the arc through which the second member 130 has been rotated 210 about the one or more hinges 140. In one or more embodiments, the second distance can range from as little as about 6 mm; about 7 mm; about 8 mm; or about 10 mm, to as much as about 12 mm; about 15 mm; about 20 mm; or about 25 mm.

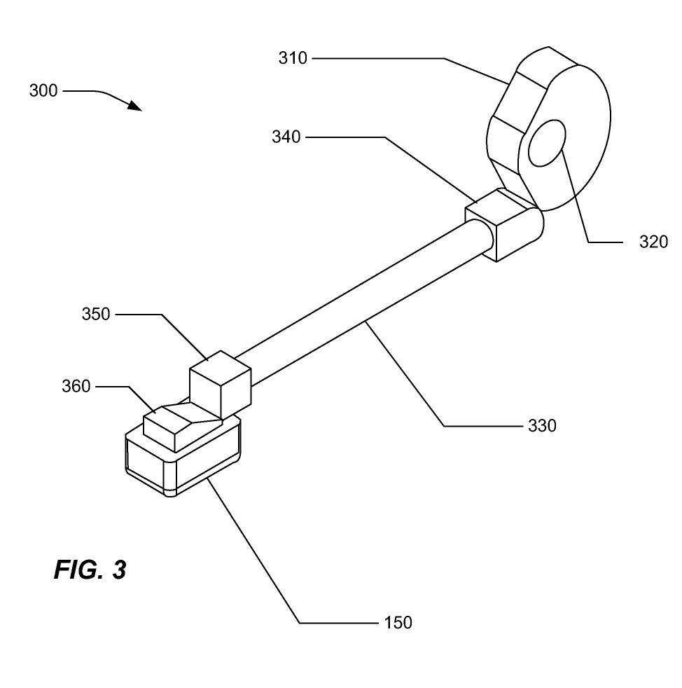

FIG. 3 is an isometric view of an exemplary actuator 300, according to one or more embodiments. In one or more embodiments, the actuator 300 can include one or more devices, systems, or combination of systems and devices suitable for the transmission or translation of rotational motion 210 applied to the second member 130 to linear motion 220 applied to the one or more feet 150. In one or more specific embodiments, the actuator 300 can include a first cam 310 operatively connected to the second member 130 such that all or a portion of the rotation of the second member 130 about the at least one hinge 140 can be translated or otherwise transmitted to the first cam 310.

In one or more embodiments, the actuator 300 can also include a connecting member 330 having a first end and a second end. In one or more embodiments, a cam follower 340 can be disposed on the first end of the connecting member 330. In one or more embodiments, a push block 350 can be disposed on the second end of the connecting member 330. In one or more embodiments, the cam follower 340 can be disposed proximate the first cam 310 and the push block 350 can be disposed proximate the one or more feet 150.

In one or more embodiments, a ramp member 360 can be disposed on or about all or a portion of the one or more feet 150. In one or more embodiments, the ramp member 360 can be separate or distinct from each of the one or more feet. In one or more embodiments, the ramp member 360 can be integral with the one or more feet 150. In one or more embodiments, the cam follower 340 can be disposed proximate the cam and the push block 350 can be disposed proximate the ramp member 360 disposed on each of the one or more feet as depicted in FIG. 3. Although the ramp member 360 can be a pyramidal structure as depicted in FIG. 3, other shapes, for example symmetrical or oblong hemispherical shapes can also be used.

In one or more embodiments, the first cam 310, the cam follower 340, and/or the push block 350 can be fabricated using any rigid material. In one or more embodiments, the connecting member 330, the cam follower 340, and/or the push block 350 can be a unitary member. In one or more embodiments, the connecting member 330, the cam follower 340, and/or the push block 350 can be a plurality of components attached or otherwise affixed together. In one or more specific embodiments, the first cam 310, the connecting member 330, the cam follower 340, and/or the push block 350 can be fabricated using a rigid, self-lubricating, material.

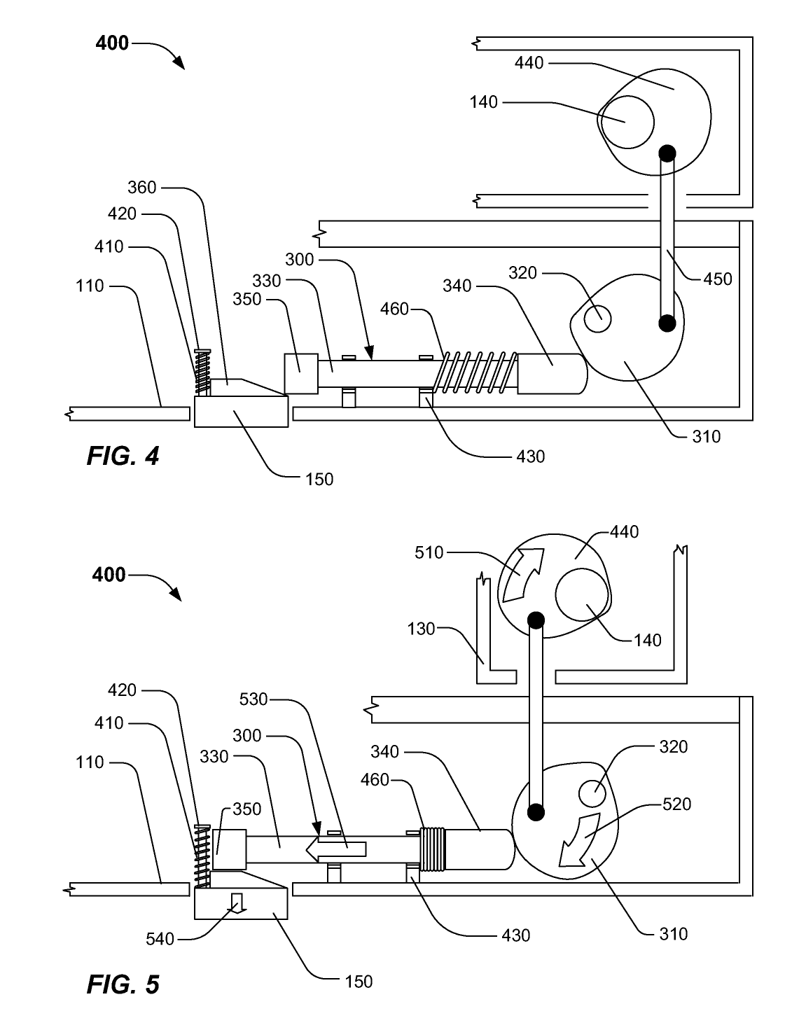

FIG. 4 is a schematic diagram depicting an exemplary foot height adjustment system 400 using the exemplary actuator 300 depicted in FIG. 3 disposed in an illustrative first position, according to one or more embodiments. In one or more embodiments, the system 400 can include, first and second members 110, 130, pivotably connected via the one or more hinges 140. One or more feet 150, each disposed in one or more apertures 155 respectively. The actuator 300 can include the first cam 310, shaft 320, connecting member 330, cam follower 340, push block 350, and ramp member 360 as depicted in, and described in detail with reference to, FIG. 3. Additionally, in one or more embodiments, the foot height adjustment system 400 can include one or more tension members 410, one or more anchor members 420, and one or more brace members 430. In one or more embodiments, one or more second cams 440 can be disposed in, on, or about the second member 130, and operably connected to the one or more cams 310 using one or more linkage members 450.

In one or more embodiments, the one or more tension members 410 can be used to bias the one or more feet 150 to the first position. In one or more embodiments, the tension member 410 can be any member suitable for developing an axial force proportional to tensile displacement, for example a tension spring or the like. In one or more specific embodiments, the tension member 410 can be a helical spring having a first end and a second end as depicted in FIG. 4. In one or more embodiments, the first end of the tension member 410 can be attached to the one or more anchor members 420, which can be, in turn, attached to the first member 110. In one or more embodiments, the one or more anchor members can be attached to the first member 110. In one or more embodiments, the second end of the tension member 410 can be attached to the one or more feet 150.

In one or more embodiments, the one or more brace members 430 can be used to limit the displacement of the one or more connecting members 300 to one or more desired planes. For example, if, as in FIG. 4, it is desirous to limit the displacement of the one or more connecting members 300 to displacement along a single axis, one or more brace members 430 can be disposed proximate the connecting member 300 to limit or prevent any displacement in the non-preferred, non-axial, lateral, direction. In one or more embodiments, the one or more brace members 430 can be fabricated using any rigid material. In one or more specific embodiments, the one or more brace members 430 can be fabricated using one or more self-lubricating materials.

In one or more embodiments, one or more second cams 440 can be disposed in, on, or about the second member 130. In one or more embodiments, the one or more second cams 440 can be attached or otherwise affixed to the second member 130 in a manner or method permitting the rotation 210 of the one or more second cams 440 in conjunction with the rotation 210 of the second member 130 about the one or more hinges 140.

In one or more embodiments, the one or more tension members 460 can be used to bias the connecting member 310 to the first position. In one or more embodiments, the tension member 460 can be any member suitable for developing an axial force proportionate to the compressive displacement of the tension member, for example a helical compression spring, a volute spring, or the like. In one or more specific embodiments, the tension member 460 can be a helical spring having a first end and a second end as depicted in FIG. 4. In one or more embodiments, the first end of the tension member 460 can be disposed proximate the cam follower 340 and the second end can be disposed proximate the one or more brace members 430.

FIG. 5 is a schematic diagram depicting the exemplary foot height adjustment system 400 depicted in FIG. 4 displaced to an illustrative second position, according to one or more embodiments. The second member 130 can be rotated 510 about the one or more hinges 140 to the second position depicted in FIG. 5. As the second member 130 is rotated 510 about the one or more hinges 140, the linkage member 450 can, in turn, rotate 520 the first cam 310. The rotation 520 of the first cam 310 can reversibly displace 530 the actuator 300 as the cam follower 340 travels about the perimeter of the first cam 310. The displacement of the actuator 300 can drive the push block 350 across the ramp member 360, thereby causing a displacement 540 of the one or more feet 150 from the first position depicted in FIG. 4 to the second position depicted in FIG. 5.

As the actuator 300 is displaced 530 the tension member 460 can be compressed between the cam follower 340 and the brace member 430. In one or more embodiments, the tension member 460 can provide all or a portion of the restorative force required to displace the actuator 300 from the second position depicted in FIG. 5 to the first position depicted in FIG. 4.

As the one or more feet 150 are displaced 540, the tensile force exerted on the tension member 410 can increase, thereby generating a force within the tension member 410. In one or more embodiments, the tension member 410 can provide all or a portion of the restorative force required to displace the one or more feet 150 from the second position depicted in FIG. 5 to the first position depicted in FIG. 4.

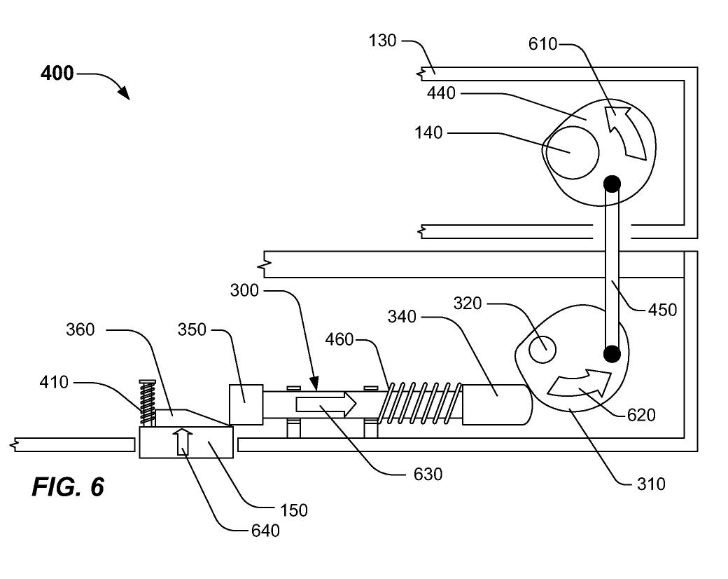

FIG. 6 is a schematic diagram depicting the exemplary foot height adjustment system 400 depicted in FIG. 4 restored to the illustrative first position, according to one or more embodiments. In one or more embodiments, the second member 130 can be rotated 610 about the one or more hinges 140, restoring the second member 130 to the first position depicted in FIG. 6.

In one or more embodiments, the second member 130 can be rotated about the one or more hinges 140. The rotation of the second member 130 about the one or more hinges 140 can cause a proportionate displacement or rotation 610 of the second cam 440. The displacement or rotation 610 of the second cam 440 can, via the linkage member 450, cause a proportionate displacement or rotation 620 of the first cam 310 about the shaft 320. The rotation 620 of the first cam 310, combined with the bias of the tension member 460, can reversibly displace 630 the connecting member 300 as the cam follower 340 travels about the perimeter of the first cam 310. The displacement 630 of the connecting member 300 can, in turn, shift the push block 350 away from the ramp member 360, thereby permitting the upward bias of the tension member 410 to retract or otherwise displace 640 the one or more feet 150 from the second position depicted in FIG. 5 to the first position depicted in FIG. 6.

Various terms have been defined above. To the extent a term used in a claim is not defined above, it should be given the broadest definition persons in the pertinent art have given that term as reflected in at least one printed publication or issued patent. Furthermore, all patents, test procedures, and other documents cited in this application are fully incorporated by reference to the extent such disclosure is not inconsistent with this application and for all jurisdictions in which such incorporation is permitted.

While the foregoing is directed to embodiments of the present invention, other and further embodiments of the invention may be devised without departing from the basic scope thereof, and the scope thereof is determined by the claims that follow.

What is claimed is:

1. A foot height adjustment system, comprising:
a clamshell device comprising a first member having an exterior surface and a pivotably connected second member, wherein the pivotable connection between the first member and the second member comprises at least one hinge;
at least one foot disposed in at least one aperture, the at least one aperture disposed in the first member, wherein the at least one foot projects a first distance from the exterior surface of the first member; and
an actuator linking the second member and the at least one foot,
wherein the actuator is adapted to reversibly increase the projection of the at least one foot from the exterior surface of the first member to a second distance when the second member is pivoted about the at least one hinge, and
wherein the second distance is greater than the first distance.

2. The system of claim 1 wherein the actuator linking the second member and the at least one foot comprises:
a first cam operatively connected to the second member, wherein the first cam rotates about a shaft in response to the rotation of the second member about the at least one hinge;
a connecting member having a cam follower disposed on a first end and a push block disposed on a second end,
wherein the cam follower is disposed proximate the first cam; and
wherein the push block is disposed proximate the at least one foot.

3. The system of claim 1, further comprising at least one tension member having a first end and a second end,
wherein the first end is affixed to the first member, and
wherein the second end is affixed to the at least one foot.

4. The system of claim 1 wherein the clamshell device is selected from the group of clamshell devices consisting of: an ultraportable personal computer; a portable personal computer, a laptop personal computer, a personal data assistant, and a cellular communications device.

5. The system of claim 1, further comprising at least one fixed foot having a fixed projection disposed on the exterior surface of the first member.

6. The system of claim 1, further comprising a ramp member disposed proximate the at least one foot and proximate the push block.

7. The system of claim 1 wherein the first distance comprises a projection above the exterior surface of the first member of from about 1 mm to about 10 mm.

8. The system of claim 1 wherein the second distance comprises a projection above the exterior surface of the first member of from about 10 mm to about 30 mm.

9. The system of claim 1, further comprising at least one brace member disposed proximate the connecting member and limiting the movement of the connecting member to a single axis.

10. A height adjustable clamshell electronic device system, comprising:
a first member and a second member pivotably connected along a single axis using at least one hinge; and
an actuator linking the second member and a plurality of adjustable feet, the plurality of adjustable feet individually disposed in a respective plurality of apertures disposed about the first member,
wherein each of the feet projects a first distance from the exterior surface of the first member when the first member and the second member forming the clamshell electronic device are disposed at a first angle; and
wherein each of the feet projects a second distance from the exterior surface of the first member when the first member and the second member forming the clamshell electronic device are disposed at a second angle.

11. The system of claim 10 wherein the actuator comprises:
a first cam operatively connected to the second member, wherein the cam rotates about a shaft in response to the pivoting of the second member about the hinge;
a member having a cam follower disposed on a first end and a push block disposed on a second end,
wherein the cam follower is disposed proximate the first cam; and
wherein the push block is disposed proximate the at least one foot.

12. The system of claim 10, further comprising at least one fixed foot having a fixed projection disposed on the exterior surface of the first member.

13. The system of claim 10, further comprising at least one tension member having a first end and a second end,
wherein the first end is affixed to the first member, and
wherein the second end is affixed to the at least one foot.

14. The system of claim 10, further comprising a ramp member disposed proximate the at least one foot and proximate the push block.

15. The system of claim 10 wherein the first distance comprises a projection above the exterior surface of the first member of from about 1 mm to about 10 mm.

16. The system of claim 10 wherein the second distance comprises a projection above the exterior surface of the first member of from about 10 mm to about 30 mm.

17. A method for adjusting the foot height a clamshell device, comprising:
pivotably connecting a first member and a second member using at least one hinge having single axis of rotation;
wherein at least one foot is disposed in at least one aperture, the aperture disposed in the first member
operably connecting the second member to the at least one foot using an actuator; and
adjusting the projection of the at least one adjustable foot from an exterior surface of the first member from a first distance to a second distance by rotating the second member about the hinge from a first position to a second position.

18. The method of claim 17 wherein the actuator comprises:
a first cam operatively connected to the at least one member, wherein the first cam rotates about a shaft in response to the pivoting of the at least one member about the hinge;
a member having a first cam follower disposed on a first end and a push block disposed on a second end,
wherein the cam follower is disposed proximate the first cam; and
wherein the push block is disposed proximate the at least one foot.

19. The method of claim 17 wherein the first distance comprises a projection above the exterior surface of the first member of from about 1 mm to about 10 mm.

20. The method of claim 17 wherein the second distance comprises a projection above the exterior surface of the first member of from about 10 mm to about 30 mm.
